(19) United States
(12) Patent Application Publication
(10) Pub. No.: US 2009/0250254 A1
(43) Pub. Date: Oct. 8, 2009

(54) METHODS FOR CONFIGURABLE MANUFACTURING AND APPARATUS

(76) Inventors: Diana A. Sufariu, Nashua, NH (US); Roberto S. Santos, Hudson, MA (US)

Correspondence Address: Rockwell Automation, Inc.;Attention: Susan M. Donahue, Patent Dept./704P Floor 8 T-29, 1201 South Second Street, Milwaukee, WI, 53204, US

(21) Appl. No.: 12/061,560

(22) Filed: Apr. 2, 2008

(51) Int. Cl. H05K 1/16; H05K 3/30

(52) U.S. Cl. 174/260; 29/832

(57) ABSTRACT

A method of manufacturing industrial controls includes partially assembling a pre-product at a first stage in manufacturing, including at least partially populating a printed circuit board with generic components and/or laser trimmable components, storing the pre-product for later manufacturing stages. The method further includes populating the printed circuit board with unique components and/or using a laser to establish unique values of the laser trimmable components at a second stage of manufacturing to form a unique model.

### TECHNICAL FIELD

The various embodiments described herein relate generally to a method of manufacturing, including manufacturing various models of sensors.

### BACKGROUND

The manufacture of industrial controls, such as sensors, often employs the use of a printed circuit board with electronic components mounted thereon. The populated printed circuit board is placed within a housing along with additional components. The sensors include a wide variety of technical performance requirements. For instance, proximity sensors come in a variety of different sizes, lengths, mounting configurations, sensing ranges, and output configurations. In an example, a 12 mm cylindrical proximity sensor may have two different housing lengths, shielded and unshielded mounting configurations, a standard and extended sensing distance, and a variety of output configurations. The wide variety of technical performance requirements may require the printed circuit board to have a variety of shapes, and for a variety of electronic components to be mounted on the printed circuit board. Each proximity sensor model has a unique set of performance requirements and has a unique printed circuit board, with a unique set of electronic components mounted thereon. This results in the need for a large number of unique printed circuit boards to be created and stocked as part of the manufacturing process.

### SUMMARY

A method of manufacturing a series of products within a product line is described herein. The method includes partially assembling a printed circuit board at a first stage in manufacturing, including partially populating the printed circuit board with generic components, where the printed circuit board is usable in all of the products within the product line, where the generic components are common to two or more products. The method further includes populating the printed circuit board with unique components at a second stage in manufacturing and creating an end product, where populating the printed circuit board with the unique components establishes performance features of the end product, and disposing the populated printed circuit board within a housing.

In another option, the method includes assembling a printed circuit board at a first stage in manufacturing, including populating the printed circuit board with generic components, where the printed circuit board is usable in all of the products within the product line, where the generic components are common to two or more products. The method further includes populating the printed circuit board with one or more laser trimmable components at a first stage in manufacturing. The method further includes using a laser at a second stage in manufacturing and creating an end product, where using the laser to trim the laser trimmable components establishes their final unique values and thereby establishes performance features of the end product, and disposing the populated printed circuit board within a housing.

In another option, the method further includes coupling the printed circuit board with an interface board. In a further option, populating the printed circuit board with unique components includes populating the printed circuit board with at least one of an oscillating frequency setting component and/or a temperature compensation component. In a further option, populating the printed circuit board with laser trimmable components includes populating the printed circuit board with at least one of an oscillating frequency setting component and/or a temperature compensation component.

An industrial control, such as a proximity sensor, is further discussed herein. The proximity sensor comprises a housing, a printed circuit board having components mounted thereon, the components including one or more generic components and one or more unique components, and the printed circuit board disposed within the housing. The sensor further includes at least one coil assembly coupled with the printed circuit board, and the at least one coil assembly is disposed within the cylindrical housing. At least one interface board is coupled between the at least one coil assembly and the printed circuit board, and the at least one interface board has a width that is greater than the printed circuit board.

In another option, the proximity sensor comprises a housing, a printed circuit board having components mounted thereon, the components including one or more generic components and one or more laser trimmable components, and the printed circuit board disposed within the housing. The sensor further includes at least one coil assembly coupled with the printed circuit board, and the at least one coil assembly is disposed within the cylindrical housing. At least one interface board is coupled between the at least one coil assembly and the printed circuit board, and the at least one interface board has a width that is greater than the printed circuit board.

Several options for the proximity sensor are as follows. For instance, the unique components include one or more oscillating frequency setting components such as, but not limited to, a capacitor. In another option, the unique components include a temperature compensation network that consists of, but is not limited to, one or more resistors and/or thermistors. In another option, the laser trimmable components include one or more oscillating frequency setting components such as, but not limited to, a laser trimmable capacitor. In another option, the laser trimmable components include a temperature compensation network that consists of, but is not limited to, one or more laser trimmable resistors.

### BRIEF DESCRIPTION OF THE DRAWINGS

FIG. 1 illustrates a perspective view of an industrial control such as an inductive proximity sensor according at least one embodiment.

FIG. 2 illustrates a cross-sectional view of an inductive proximity sensor according to at least one embodiment.

FIG. 3 illustrates a portion of an inductive proximity sensor according to at least one embodiment.

FIG. 4 illustrates a cross-sectional view of an inductive proximity sensor according to at least one embodiment.

FIG. 5 illustrates a portion of an inductive proximity sensor according to at least one embodiment.

FIG. 6 illustrates an exploded cross-sectional side view of an inductive proximity sensor according to at least one embodiment.

### DETAILED DESCRIPTION

The following detailed description refers to the accompanying drawings that show, by way of illustration, specific details and embodiments in which the invention may be practiced. These embodiments, which are also referred to herein as “examples,” or “options” are described in sufficient detail to enable those skilled in the art to practice the invention.

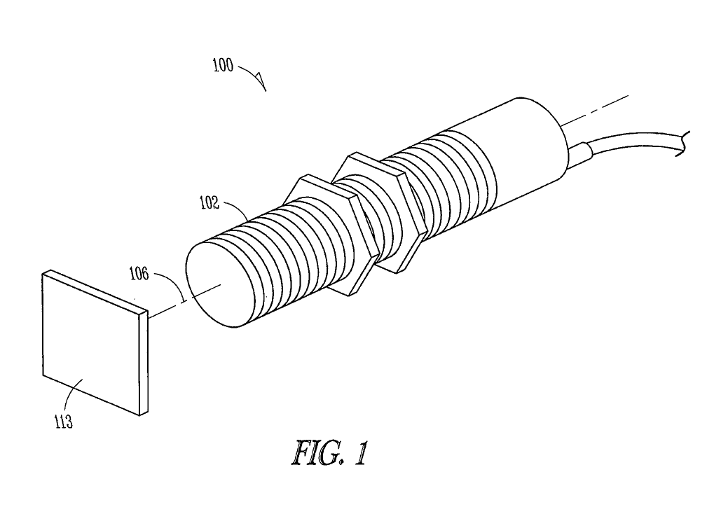

A method of manufacturing a series or products within a produc line is described herein. FIG. 1 illustrates an example of an industrial control, such as a proximity sensor 100 for sensing one or more objects 113, that can be manufactured using one or more of the methods. The proximity sensor has an elongate cylindrical housing 102. The housing 102 can have a variety of shapes. For instance, the housing 102 can have a rectangular prism shape, cube shape, or other shapes. The housing 102 is defined in part by a longitudinal axis 106. The proximity sensor 100 includes internal electronics, such as sensing circuitry, such as that for an inductive type of proximity sensor.

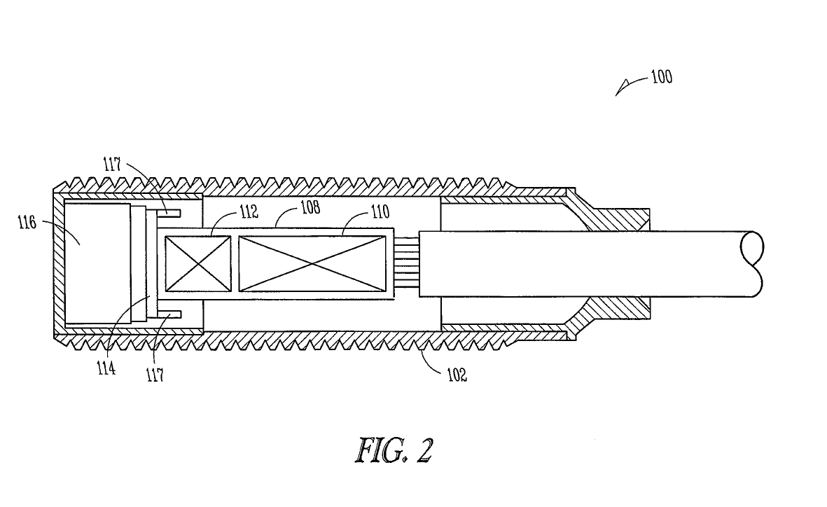

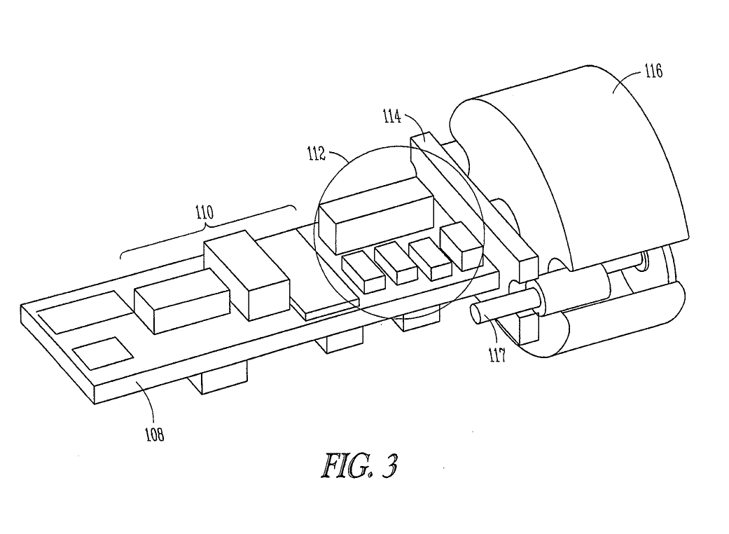

Referring to FIGS. 2 and 3, a printed circuit board 108 includes components mounted thereon, and the printed circuit board 108 is disposed within the housing 102. The components include generic components 110 and one or more unique components 112. The generic components 110 are common to several different models and versions of the proximity sensor 100, and in an option, the generic components 110 are common for all possible model configurations. The unique components 112 are unique to the various models of the sensors. The generic components 110 are populated onto the printed circuit board 108 to form a pre-product at a first stage in manufacturing. The printed circuit board 108 having the generic components 110 is usable in all of the products within the product line. The pre-product can be stored, such as stocked, and used for several or all models of the sensor, to be determined at a later stage in manufacturing. The printed circuit board 108 is partially assembled at this first stage of manufacturing.

The unique components 112 are populated at a second stage in manufacturing to create an end product. The population of the unique components 112 establishes performance features of the end product, to create a unique model. In an option, the unique components 112 include one or more oscillating frequency setting components such as, but not limited to, a capacitor. In another option, the unique components 112 include one or more temperature compensation components, such as resistors and/or thermistors, that form the temperature compensation network. The assembly is coupled with other components, if necessary, and disposed within a housing.

The sensor 100 further includes an interface board 114 and at least one coil assembly 116. The at least one interface board 114 is coupled between the at least one coil assembly 116 and the printed circuit board 108, for example after the second stage in manufacturing. The at least one interface board 114, the at least one coil assembly 116, and the printed circuit board 108 are disposed within the housing 102. In an option, the at least one coil assembly 116 has a diameter that is greater than the width of the printed circuit board 108. The printed circuit board 108, with the generic components 110 and unique components 112, is connected with the interface board 114, for example by soldering the printed circuit board 108 with the interface board 114. The interface board 114 is coupled with the at least one coil assembly 116, for example, by use of bobbin pins 117. The shape of the interface board 114 is optionally rectangular, and is disposed transverse to the plane of the printed circuit board 108.

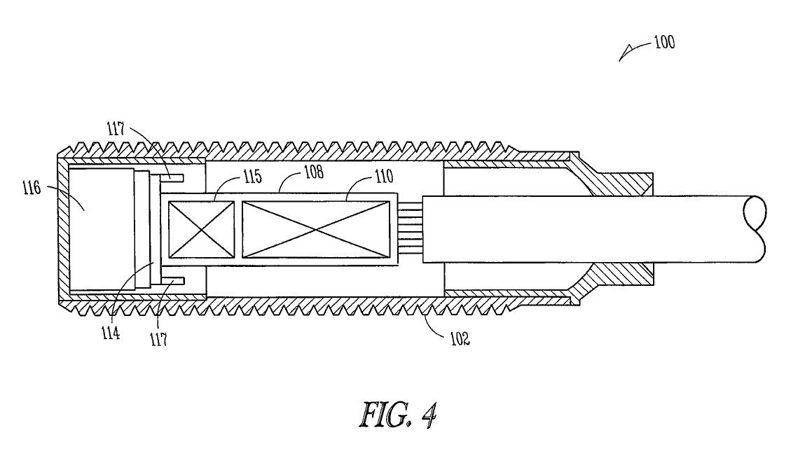

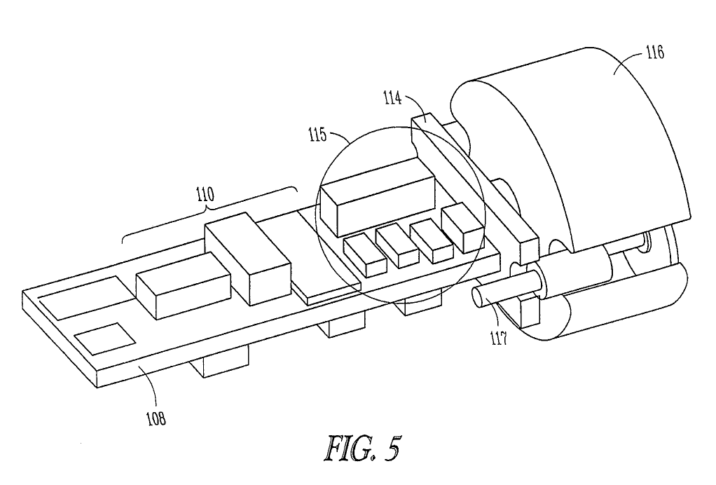

Referring to FIGS. 4 and 5, a printed circuit board 108 includes components mounted thereon, and the printed circuit board 108 is disposed within the housing 102. The components include generic components 110 and one or more laser trimmable components 115. The generic components 110 are common to several different models and versions of the proximity sensor 100, and in an option, the generic components 110 and laser trimmable components 115 are common for all possible model configurations. The generic components 110 and laser trimmable components 115 are populated onto the printed circuit board 108 to form a pre-product at a first stage in manufacturing, wherein the printed circuit board 108 having the generic components 110 and laser trimmable components 115 is usable in all of the products within the product line. The pre-product can be stored, such as stocked, and used for several or all models of the sensor, to be determined at a later stage in manufacturing. The printed circuit board 108 is partially assembled at this first stage of manufacturing.

The use of a laser at a second stage of manufacturing to trim the laser trimmable components 115 can be used to establish their final values, which may be unique to each model, and thereby establishes performance features of the end product, to create a unique model. In an option, the laser trimmable components 115 include one or more oscillating frequency setting components such as, but not limited to, a laser trimmable capacitor. In another option, the laser trimmable components 115 include one or more temperature compensation network components such as, but not limited to, a laser trimmable resistor. The assembly is coupled with other components, if necessary, and disposed within a housing.

The sensor 100 further includes an interface board 114 and at least one coil assembly 116. The at least one interface board 114 is coupled between the at least one coil assembly 116 and the printed circuit board 108, for example after a second stage in manufacturing. The at least one interface board 114, the at least one coil assembly 116, and the printed circuit board 108 are disposed within the housing 102. In an option, the at least one coil assembly 116 has a diameter that is greater than the width of the printed circuit board 108. The printed circuit board 108, with the generic components 110 and laser trimmable components 115, is connected with the interface board 114, for example by soldering the printed circuit board 108 with the interface board 114. The interface board 114 is coupled with the at least one coil assembly 116, for example, by use of bobbin pins 117. The shape of the interface board 114 is optionally rectangular, and is disposed transverse to the plane of the printed circuit board 108.

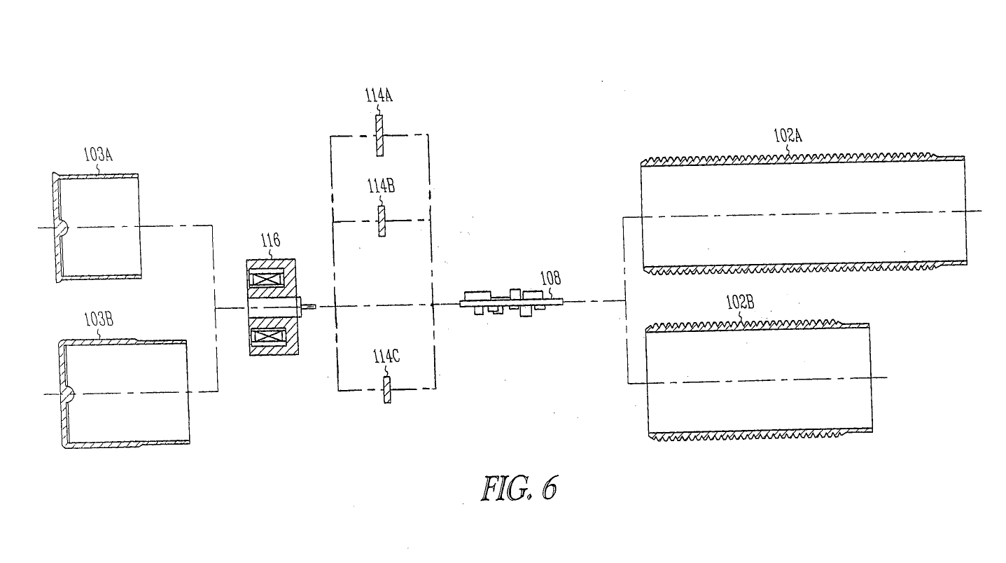

FIG. 6 illustrates an example apparatus using at least one of the methods herein. The printed circuit board 108 is sized to be received in multiple housings. The housings are formed from components 102a or 102b and 103a or 103b. The components 102a, 102b, 103a, 103b are interchangeable, where 103a can be used with either 102a or 102b to form various housings. In addition, 103b can be used with either 102a or 102b to form various housings. The printed circuit board 108 is populated, in an option, with generic components, which are common to all possible models at a first stage of manufacturing. At a second stage of manufacturing, the unique components are selected and populated onto the printed circuit board 108, which determines performance features of the sensor such as the oscillating frequency and/or temperature compensation. In a further option, the printed circuit board 108 is populated with generic components and laser trimmable components, which are common to all possible models, at a first stage of manufacturing. At a second stage of manufacturing, a laser is used to establish the value of at least one of the laser trimmable components on the printed circuit board 108. For example, a trimmable resistor is laser trimmed to set its resistance value. The interface board 114a, 114b, 114c, in an option, is selected based on the diameter of the coil assembly 116 and assembled after the second stage of manufacturing.

The methods herein can be used to stock fewer populated printed circuit boards to form several different components at the second or final stage of manufacturing, instead of stocking several different populated printed circuit boards for final assembly. While these methods have been discussed relative to proximity sensors, it is possible these methods can be used to form other sensors such as, but not limited to, photoelectric sensors.

The above Detailed Description is intended to be illustrative, and not restrictive. The various embodiments are not necessarily mutually exclusive, as some embodiments can be combined with one or more other embodiments to form new embodiments. For example, the above-described embodiments (and/or aspects thereof) embodiments may be combined, utilized and derived therefrom, such that structural and logical substitutions and changes may be made without departing from the scope of this disclosure. Such embodiments of the inventive subject matter may be referred to herein, individually and/or collectively, by the term “invention” merely for convenience and without intending to voluntarily limit the scope of this application to any single invention or inventive concept if more than one is in fact disclosed. Many other embodiments will be apparent to those of skill in the art upon reviewing the above description. The scope of the invention should, therefore, be determined with reference to the appended claims, along with the full scope of equivalents to which such claims are entitled.

The methods described herein do not have to be executed in the order described, or in any particular order, unless it is otherwise specified that a particular order is required. Moreover, unless otherwise specified, various activities described with respect to the methods identified herein can be executed in repetitive, simultaneous, serial, or parallel fashion.

The terms “a” or “an” are used, as is common in patent documents, to include one or more than one. The term “or” is used to refer to a nonexclusive or, unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The Abstract of the Disclosure is provided to comply with 37 C.F.R. §1.72(b), requiring the abstract that will allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separate embodiment with each embodiment being combinable with each other embodiment.

What is claimed is:

1. A method of manufacturing a series of products within a product line, the method comprising:
partially assembling a printed circuit board at a first stage in manufacturing, including partially populating the printed circuit board with generic components, where the printed circuit board is usable in all of products within the product line, where the generic components are common to two or more products;
populating the printed circuit board with unique components at a second stage in manufacturing and creating an end product, where populating the printed circuit board with the unique components establishes performance features of the end product; and
disposing the populated printed circuit board within a housing.

2. The method as recited in claim 1, further comprising coupling the printed circuit board with an interface board after a second stage in manufacturing.

3. The method as recited in claim 1, wherein populating the printed circuit board with unique components includes populating the printed circuit board with at least one oscillating frequency setting component.

4. The method as recited in claim 1, wherein populating the printed circuit board with unique components includes populating the printed circuit board with at least one temperature compensation component.

5. The method as recited in claim 1, further comprising forming a proximity sensor.

6. The method as recited in claim 1, further comprising forming a photoelectric sensor.

7. A method of manufacturing a series of products within a product line, the method comprising:
partially assembling a printed circuit board at a first stage in manufacturing, including populating the printed circuit board with generic components and laser trimmable components, where the printed circuit board is usable in all of products within the product line, where the generic components are common to two or more products;
laser trimming at least one of the laser trimmable components at a second stage in manufacturing and creating an end product, where laser trimming the trimmable components on the printed circuit board establishes performance features of the end product; and
disposing the populated printed circuit board within a housing.

8. The method as recited in claim 7, further comprising coupling the printed circuit board with an interface board after a second stage in manufacturing.

9. The method as recited in claim 7, wherein laser trimming the at least one laser trimmable component changes a value of the at least one component.

10. The method as recited in claim 7, wherein populating the printed circuit board with laser trimmable components includes populating the printed circuit board with at least one oscillating frequency setting component.

11. The method as recited in claim 7, wherein populating the printed circuit board with laser trimmable components includes populating the printed circuit board with at least one temperature compensation component.

12. The method as recited in claim 7, further comprising forming a proximity sensor.

13. The method as recited in claim 7, further comprising forming a photoelectric sensor.

14. A proximity sensor comprising:
a housing;
a printed circuit board having components mounted thereon, the components include one or more generic components and one or more unique components, the printed circuit board disposed within the housing;
at least one coil assembly coupled with the printed circuit board, the at least one coil assembly disposed within the cylindrical housing; and
at least one interface board coupled between the at least one coil assembly and the printed circuit board, and the at least one interface board has a width that is greater than the printed circuit board.

15. The proximity sensor as recited in claim 14, wherein the unique components include one or more oscillating frequency setting components.

16. The proximity sensor as recited in claim 15, wherein the one or more oscillating frequency setting components is a capacitor.

17. The proximity sensor as recited in claim 14, wherein the unique components include one or more temperature compensation network components.

18. The proximity sensor as recited in claim 17, wherein the one or more temperature compensation network components includes one or more of a resistor or thermistor.

19. The proximity sensor as recited in claim 14, wherein the interface board has a generally rectangular shape.

20. The proximity sensor as recited in claim 14, wherein the printed circuit board is manufactured to allow the printed circuit board to be used with two or more different housing lengths.
